(19) United States
(12) Patent Application Publication
(10) Pub. No.: US 2025/0132236 A1
(43) Pub. Date: Apr. 24, 2025

(54) PACKAGE SUBSTRATE AND FABRICATING METHOD THEREOF

(71) Applicant: SILICONWARE PRECISION INDUSTRIES CO., LTD., Taichung City (TW)

(72) Inventors: Pao-Hung TSENG, Taichung City (TW); Yu-Cheng PAI, Taichung City (TW); Yuan-Ping YEH, Taichung City (TW)

(21) Appl. No.: 18/596,804

(22) Filed: Mar. 6, 2024

(30) Foreign Application Priority Data
Oct. 24, 2023 (TW) 112140637

(51) Int. Cl. H01L 23/498; H01L 21/48; H01L 23/13; H01L 23/14

(52) U.S. Cl. CPC H01L 23/49822; H01L 21/4857; H01L 23/13; H01L 23/142; H01L 23/49838

(57) ABSTRACT

A package substrate and a fabricating method thereof are provided, in which a core board body is provided, a first organic conductive layer and a second metal layer are sequentially formed on a first metal layer of the core board body, and portions of the first organic conductive layer and the first metal layer are removed respectively according to a pattern of the second metal layer, such that the second metal layer, or the second metal layer, the first organic conductive layer and the first metal layer are served as a first circuit layer. Therefore, the design of the organic conductive layer can facilitate the control of the side etching amount of the metal circuit during etching, enabling the production of circuit layer with fine line width/fine line pitch.

### BACKGROUND

### 1. Technical Field

The present disclosure relates to a semiconductor structure, and more particularly, to a package substrate used for a package structure and a fabricating method thereof.

### 2. Description of Related Art

In order to comply with the development trend of semiconductor packages with light, thin, short, small, multi-function, high speed, high circuit density and high frequency, package substrates have been developed toward fine circuits and small apertures. The circuit dimension of existing package substrate fabricating process has been reduced from 100 micrometers (traditional) to 30 micrometers or less.

FIG. 1A, FIG. 1B, FIG. 1C-1 and FIG. 1D-1 are schematic cross-sectional views showing a fabricating method of a conventional package substrate 1.

As shown in FIG. 1A, a core board 10 is provided and has two opposite surfaces 10a, 10b having metal layers 11, and at least one through-hole 100 is formed in the core board 10 and the metal layers 11.

As shown in FIG. 1B, a copper layer 12 is formed on the sidewalls of the through-hole 100 and the metal layers 11.

As shown in FIG. 1C-1, a patterned metal layer 13 is formed on the metal layers 11, and portions of the copper layer 12 are exposed.

As shown in FIG. 1D-1, the exposed portions of the copper layer 12 and the metal layers 11 at the positions corresponding to the exposed portions of the copper layer 12 are etched to expose portions of the core board 10.

Moreover, FIG. 1C-2 shows that the circuit formed in the conventional package substrate 1 has a line width W1 and a line pitch D1 before etching the metal layers 11 and the copper layer 12, and FIG. 1D-2 shows that the circuit formed in the conventional package substrate 1 has a line width W1′ and a line pitch D1′ after etching the metal layers 11 and the copper layer 12.

In specific, when etching the metal layers 11 and the copper layer 12, chemical liquid will simultaneously etch the circuit, causing the line width W1′ after the etching to be less than the line width W1 before the etching, and also causing the line pitch D1′ after the etching to be greater than the line pitch D1 before the etching, thereby resulting in line width loss and reducing the reliability of the circuit. For instance, the line width W1′ after the etching is less than the line width W1 before the etching, and the line pitch D1′ after the etching is greater than the line pitch D1 before the etching.

Therefore, how to overcome the various problems of the above-mentioned prior art to reduce the side etching amount of circuit during etching copper, so as to reduce the loss of line width and to achieve finer line pitch, has become an urgent problem to be solved at present.

### SUMMARY

In view of the aforementioned shortcomings of the prior art, the present disclosure provides a package substrate, which comprises: a core board body having a core layer and a first metal layer formed on two opposite surfaces of the core layer; a first organic conductive layer formed on the first metal layer; and a patterned second metal layer formed on the first organic conductive layer, wherein the first organic conductive layer and the first metal layer are formed with patterns corresponding to the second metal layer, and the second metal layer, the first organic conductive layer and the first metal layer are served as a first circuit layer.

The present disclosure further provides a method of fabricating a package substrate, the method comprises: providing a core board body, wherein the core board body has a core layer and a first metal layer formed on two opposite surfaces of the core layer; forming a first organic conductive layer on the first metal layer; forming a patterned second metal layer on the first organic conductive layer; and removing portions of the first organic conductive layer and the first metal layer respectively according to a pattern of the second metal layer, wherein the second metal layer, the first organic conductive layer and the first metal layer are served as a first circuit layer.

In the aforementioned package substrate and method, the present disclosure further comprises a second circuit layer formed on and electrically connected to the first circuit layer, wherein the second circuit layer and the first circuit layer or another second circuit layer have a dielectric layer formed therebetween.

In the aforementioned package substrate and method, the second circuit layer comprises: a third metal layer formed on the dielectric layer; a second organic conductive layer formed on the third metal layer; and a fourth metal layer formed on the second organic conductive layer, wherein the second organic conductive layer and the third metal layer are formed with patterns corresponding to a pattern of the fourth metal layer, and the fourth metal layer, the second organic conductive layer and the third metal layer are served as the second circuit layer.

In the aforementioned package substrate and method, the first circuit layer and the second circuit layer are formed with a plurality of patterned openings.

In the aforementioned package substrate and method, the first organic conductive layer and the second organic conductive layer are made of graphite.

In the aforementioned package substrate and method, a thickness of the first organic conductive layer and a thickness of the second organic conductive layer are at least 0.3 μm.

In the aforementioned package substrate and method, a thickness of the first metal layer and a thickness of the third metal layer are 1.5 μm to 2.5 μm.

In the aforementioned package substrate and method, a line pitch of the first circuit layer and a line pitch of the second circuit layer are 10 μm to 13 μm.

In the aforementioned package substrate and method, the present disclosure further comprises an insulating layer formed on the second circuit layer and having an opening; and an electrode pad formed in the opening and electrically connected to the second circuit layer.

It can be seen from the above that in the package substrate and the fabricating method thereof of the present disclosure, the design of the organic conductive layer facilitates the control of the side etching amount of the metal circuit during etching, that is, the organic conductive layer is firstly removed by a chemical liquid that does not etch copper, and then the copper at the bottom is etched. Therefore, the present disclosure utilizes the organic conductive layer to replace the copper layer of the conventional modified semi-additive process (MSAP) so as to reduce the side etching amount of circuit in the prior art, thus the required circuit layer with fine line width/fine line pitch can be fabricated by using the improved MSAP fabricating process.

### BRIEF DESCRIPTION OF THE DRAWINGS

FIG. 1A, FIG. 1B, FIG. 1C-1 and FIG. 1D-1 are schematic cross-sectional views showing a fabricating method of a conventional package substrate.

FIG. 1C-2 is a schematic partial cross-sectional view of FIG. 1C-1.

FIG. 1D-2 is a schematic partial cross-sectional view of FIG. 1D-1.

FIG. 2A, FIG. 2B, FIG. 2C-1, FIG. 2D-1 and FIG. 2E-1 are schematic cross-sectional views illustrating a fabricating method of a package substrate according to a first embodiment of the present disclosure.

FIG. 2C-2 is a schematic partial cross-sectional view of FIG. 2C-1.

FIG. 2D-2 is a schematic partial cross-sectional view of FIG. 2D-1.

FIG. 2E-2 is a schematic partial cross-sectional view of FIG. 2E-1.

FIG. 3A to FIG. 3E are schematic cross-sectional views illustrating a fabricating method of a package substrate according to a second embodiment of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “above,” “on,” “first,” “second,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

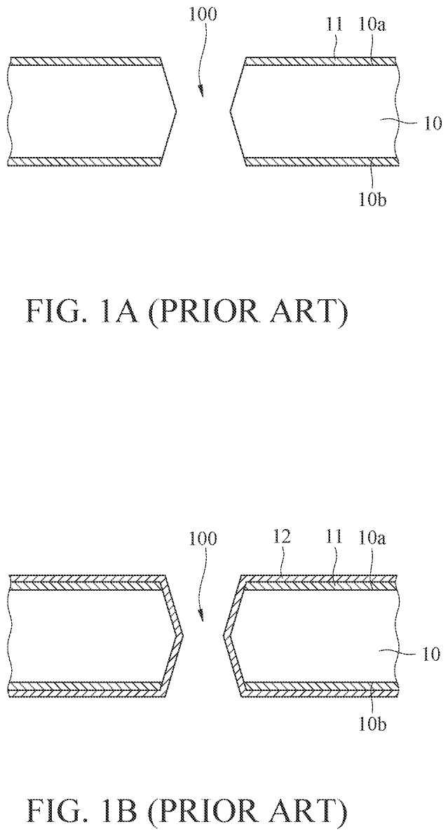

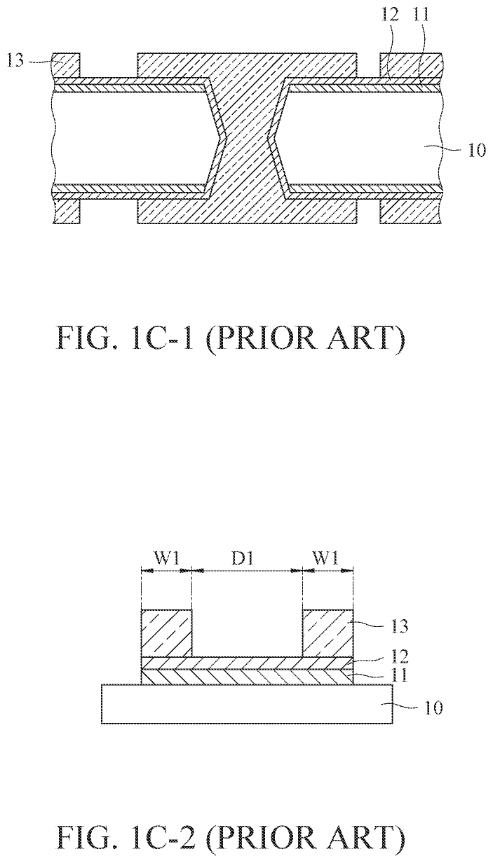

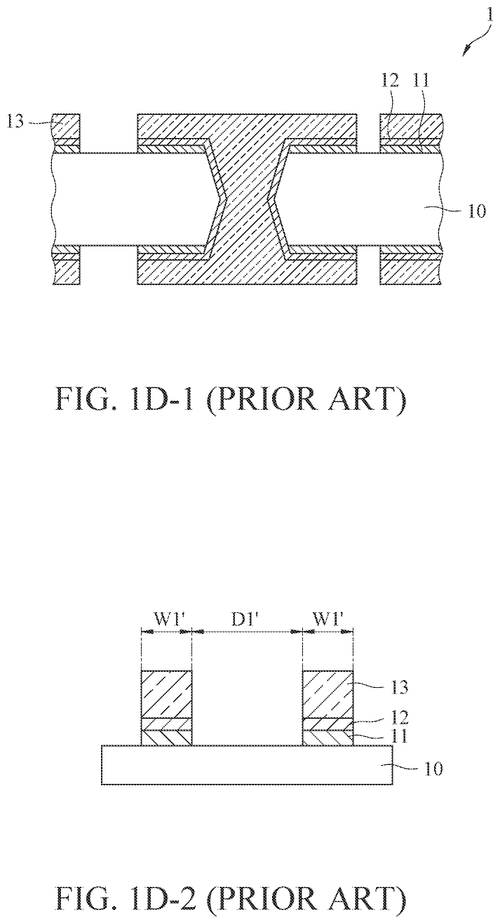

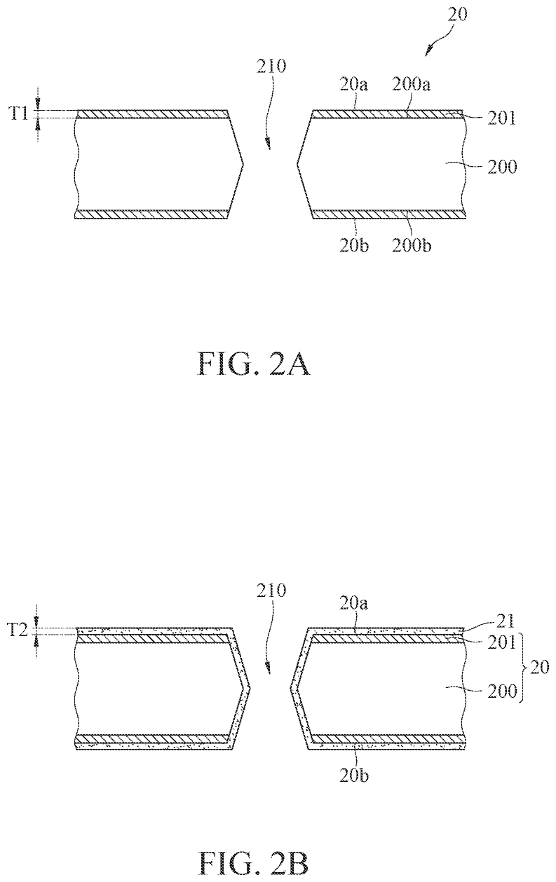

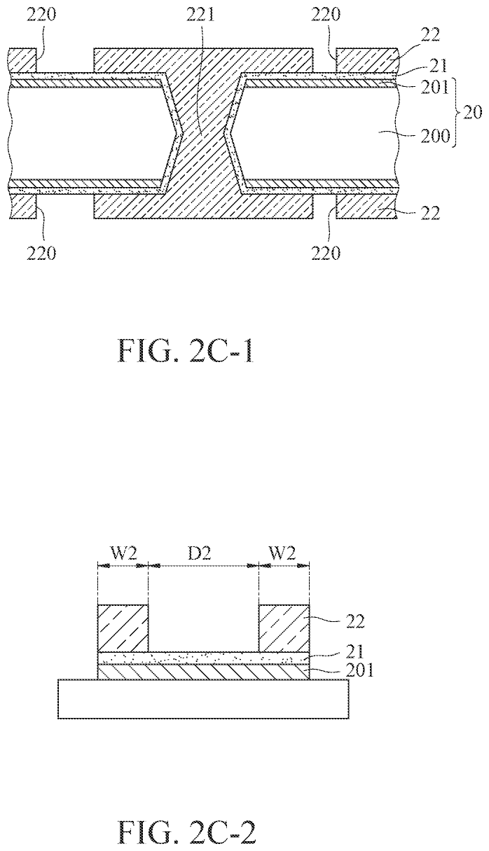

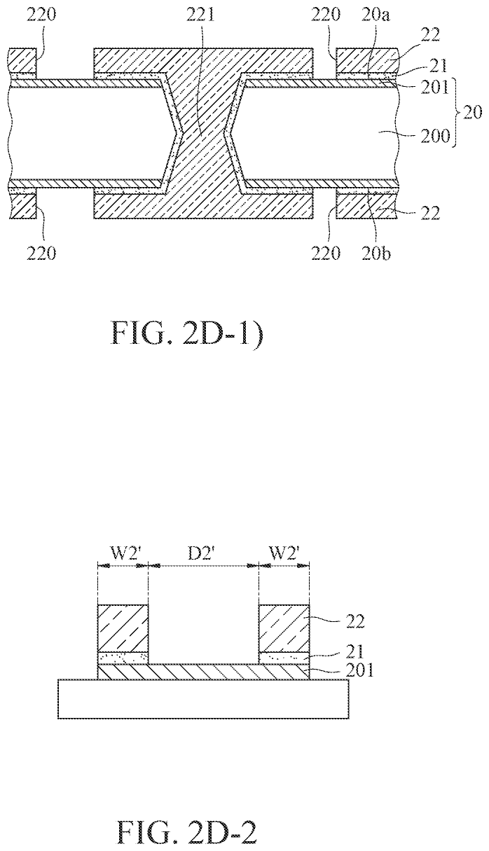

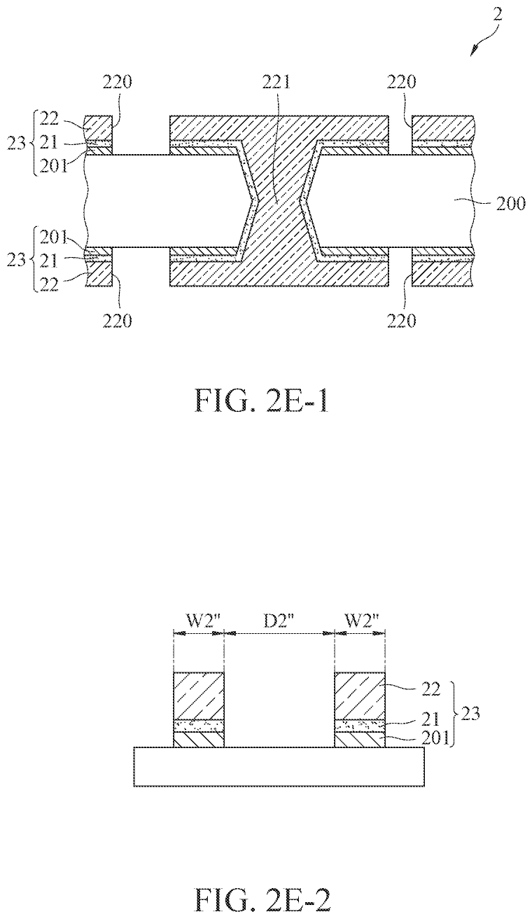

FIG. 2A, FIG. 2B, FIG. 2C-1, FIG. 2D-1 and FIG. 2E-1 are schematic cross-sectional views illustrating a fabricating method of a package substrate 2 according to a first embodiment of the present disclosure.

As shown in FIG. 2A to FIG. 2B, a core board body 20 having at least one through-hole 210 is provided, and then a first organic conductive layer 21 is formed on the core board body 20 and in the through-hole 210.

In an embodiment, the core board body 20 has two opposite surfaces 20a, 20b. For instance, the core board body 20 is a copper foil substrate (a copper clad laminate [CCL]) and includes a core layer 200, and a first metal layer 201 such as a copper foil is formed on two opposite surfaces 200a, 200b of the core layer 200. Specifically, the core layer 200 is made of a base material containing glass fiber and organic resin, such as bismaleimide triazine (BT), FR4 (FR stands for flame retardant), or FR5, and the first organic conductive layer 21 is made of graphite, but the present disclosure is not limited to as such.

In an embodiment, a thickness T1 of the first metal layer 201 is about 1.5 μm to 2.5 μm, and a thickness T2 of the first organic conductive layer 21 is at least 0.3 μm, so as to obtain easily a fine circuit structure.

In an embodiment, the through-hole 210 penetrating through the first metal layer 201 and the core layer 200 is formed by mechanics, laser, etching, or other appropriate means.

As shown in FIG. 2C-1, a patterned second metal layer 22 is formed on the first organic conductive layer 21, and portions of the first organic conductive layer 21 are exposed from the second metal layer 22.

In an embodiment, a patterned metal material (i.e., the second metal layer 22) is formed on the first organic conductive layer 21 by electroplating copper, and the second metal layer 22 has a plurality of first patterned openings 220, and the at least one through-hole 210 of the core board body 20 is filled up with the metal material to form at least one first conductive structure 221, wherein the second metal layer 22 and the first conductive structure 221 are made of copper.

As shown in FIG. 2D-1 to FIG. 2E-1, a first circuit layer 23 is formed on the two opposite surfaces 200a, 200b of the core layer 200 and on the first conductive structure 221, such that the first circuit layer 23 is electrically connected to the first conductive structure 221, thereby forming the package substrate 2.

In an embodiment, the first circuit layer 23 is fabricated by the modified semi-additive process (MSAP). In specific, in the fabricating process of the first circuit layer 23, the first organic conductive layer 21 is firstly formed on the two opposite surfaces 20a, 20b of the core board body 20 and in the through-hole 210, and then the second metal layer 22 is formed on the first organic conductive layer 21, and the second metal layer 22 is formed with the plurality of first patterned openings 220, such that portions of the first organic conductive layer 21 are exposed from the plurality of first patterned openings 220. Subsequently, as shown in FIG. 2D-1, portions of the first organic conductive layer 21 exposed from the plurality of first patterned openings 220 are removed, such that the first metal layer 201 is exposed from the plurality of first patterned openings 220. Afterwards, as shown in FIG. 2E-1, portions of the first metal layer 201 exposed from the plurality of first patterned openings 220 are removed to expose portions of the core layer 200, such that the second metal layer 22, or the second metal layer 22 with the first organic conductive layer 21 and the first metal layer 201 beneath the second metal layer 22 are served as the first circuit layer 23.

In addition, as shown in FIG. 2C-2 and FIG. 2D-2, the first organic conductive layer 21 is first removed by an etching liquid that does not etch the copper, and the second metal layer 22 can be prevented from being etched, so that a line width W2 and a line pitch D2 before removing the first organic conductive layer 21 and a line width W2′ a line pitch D2′ after removing the first organic conductive layer 21 remain the same. Moreover, as shown in FIG. 2E-2, bottom copper etching is performed to the first metal layer 201 so as to form the first circuit layer 23, wherein the line width W2′ before removing the first metal layer 201 is greater than or equal to a line width W2″ after removing the first metal layer 201, and the line pitch D2′ before removing the first metal layer 201 is less than or equal to a line pitch D2″ after removing the first metal layer 201. Therefore, compared to the prior art, the present disclosure can reduce the side etching amount of circuit during etching copper, so as to reduce the loss of line width and to achieve finer pitch of circuit.

In an embodiment, the line pitch D2″ of the first circuit layer 23 is about 10 μm to 13 μm.

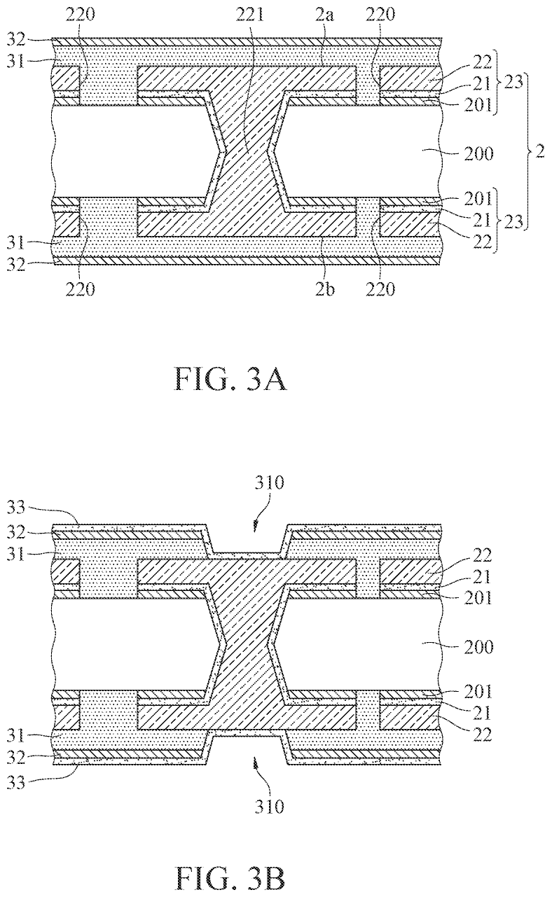

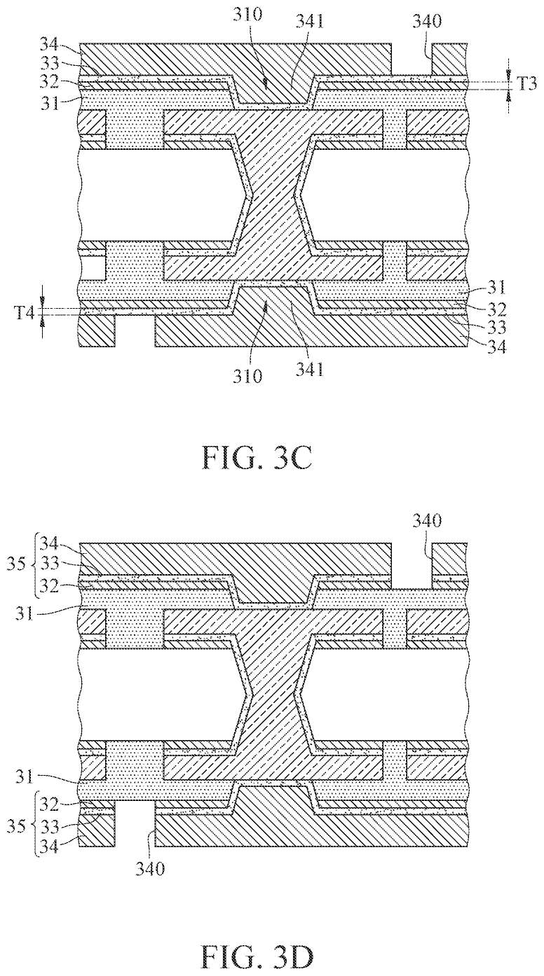

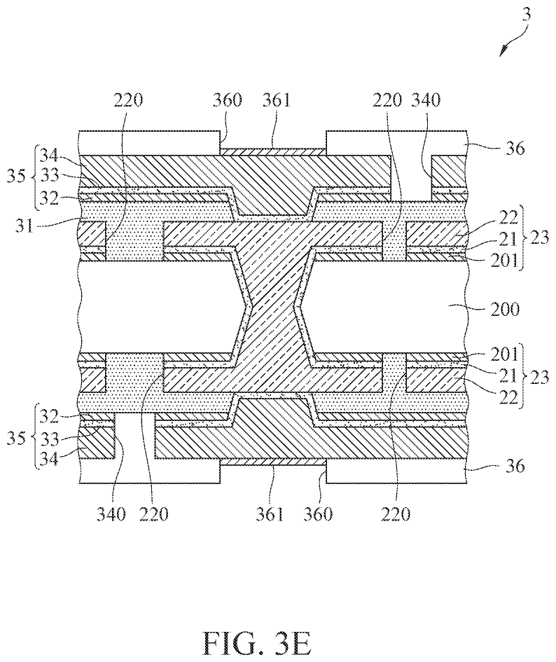

FIG. 3A to FIG. 3E are schematic cross-sectional views illustrating a fabricating method of a package substrate 3 according to a second embodiment of the present disclosure.

As shown in FIG. 3A, subsequent to the fabricating process of FIG. 2E-1, a dielectric layer 31 and a third metal layer 32 are formed on two opposite surfaces 2a, 2b of the package substrate 2.

In an embodiment, the dielectric layer 31 is formed on the first circuit layer 23 and in the plurality of first patterned openings 220 of the package substrate 2, wherein the plurality of first patterned openings 220 are filled up with the dielectric layer 31, and the dielectric layer 31 is in contact with portions of the core layer 200, so as to make the package substrate 2 flat via the dielectric layer 31. Then, the third metal layer 32 is formed on the dielectric layer 31, wherein the dielectric layer 31 is made of dielectric material such as polybenzoxazole (PBO), polyimide (PI), prepreg (PP) and the like, and the third metal layer 32 is made of copper.

As shown in FIG. 3B, a plurality of second patterned openings 310 are formed in the dielectric layer 31 and the third metal layer 32, and a second organic conductive layer 33 is formed on the third metal layer 32 and in the second patterned openings 310.

In an embodiment, portions of the third metal layer 32 and the dielectric layer 31 beneath the third metal layer 32 are removed by etching or laser to form the plurality of second patterned openings 310, so that portions of the first circuit layer 23 (i.e., the second metal layer 22) are exposed from the plurality of second patterned openings 310. Then, the second organic conductive layer 33 is formed on the third metal layer 32 and in the plurality of second patterned openings 310, and the second organic conductive layer 33 is electrically connected to portions of the first circuit layer 23, wherein the second organic conductive layer 33 is made of graphite.

In an embodiment, a thickness T3 of the third metal layer 32 is about 1.5 μm to 2.5 μm, and a thickness T4 of the second organic conductive layer 33 is at least 0.3 micrometers (μm), so as to obtain easily a fine circuit structure.

As shown in FIG. 3C, a patterned fourth metal layer 34 is formed on the second organic conductive layer 33, and portions of the second organic conductive layer 33 are exposed from the fourth metal layer 34.

In an embodiment, a patterned metal material (i.e., the fourth metal layer 34) is formed on the second organic conductive layer 33 by electroplating copper, and the fourth metal layer 34 has a plurality of third patterned openings 340, and the plurality of second patterned openings 310 are filled with the metal material to form a second conductive structure 341 in the plurality of second patterned openings 310, wherein the fourth metal layer 34 and the second conductive structure 341 are made of copper.

As shown in FIG. 3D, a second circuit layer 35 is formed on two opposite surfaces 2a, 2b of the package substrate 2 and on the second conductive structure 341, and the second circuit layer 35 covers and is electrically connected to the first circuit layer 23, so as to form the package substrate 3.

In an embodiment, the second circuit layer 35 is also fabricated by the modified semi-additive process (MSAP), and the fabricating method of the second circuit layer 35 is substantially the same with the fabricating method of the first circuit layer 23. In specific, in the fabricating process of the second circuit layer 35, the dielectric layer 31 and the third metal layer 32 are sequentially formed on the two opposite surfaces 2a, 2b of the package substrate 2, and portions of the third metal layer 32 and the dielectric layer 31 beneath the third metal layer 32 are removed to form the plurality of second patterned openings 310. Subsequently, the second organic conductive layer 33 is formed on the third metal layer 32 and in the plurality of second patterned openings 310, and then the fourth metal layer 34 is formed on the second organic conductive layer 33, and the fourth metal layer 34 is formed with the plurality of third patterned openings 340, such that portions of the second organic conductive layer 33 are exposed from the plurality of third patterned openings 340.

Afterwards, portions of the second organic conductive layer 33 exposed from the plurality of third patterned openings 340 are removed, such that the third metal layer 32 is exposed from the plurality of third patterned openings 340. Then, portions of the third metal layer 32 exposed from the plurality of third patterned openings 340 are removed to expose portions of the dielectric layer 31, such that the fourth metal layer 34, or the fourth metal layer 34 with the second organic conductive layer 33 and the third metal layer 32 beneath the fourth metal layer 34 are served as the second circuit layer 35, and the second circuit layer 35 is electrically connected to the first circuit layer 23 via portions of the second conductive structure 341 and the second organic conductive layer 33.

In an embodiment, the line pitch of the second circuit layer 35 is about 10 μm to 13 μm.

In an embodiment, the aforementioned fabricating method of the second circuit layer 35 can be repeated to stack and form a plurality of the second circuit layers 35. In other words, one layer of the first circuit layer 23 and at least one layer of the second circuit layer 35 can be formed on the two opposite surfaces 20a, 20b of the core board body 20 by the aforementioned fabricating method, wherein the dielectric layer 31 is disposed between circuit layers.

As shown in FIG. 3E, an insulating layer 36 with at least one opening 360 is formed on the second circuit layer 35 to cover the second circuit layer 35.

In an embodiment, the insulating layer 36 is formed on the second circuit layer 35, and portions of the insulating layer 36 are removed to form at least one opening 360, and portions of the second circuit layer 35 are exposed from the opening 360, so as to form an electrode pad 361 electrically connected to the second circuit layer 35 in the opening 360, and the electrode pad 361 is provided for electrical connection to external devices, wherein the insulating layer 36 is made of epoxy resin such as green paint.

In the fabricating method of the package substrate 2, 3 of the present disclosure, the designs of the first organic conductive layer 21 and the second organic conductive layer 33 facilitate the control of the side etching amount of the metal circuit during etching, that is, the first organic conductive layer 21 and the second organic conductive layer 33 are firstly removed by a chemical liquid that does not etch copper, and then the copper at the bottom is etched, thus the side etching amount of the circuit is only related to the thickness of the bottom copper (such as the first metal layer 201 and the third metal layer 32), so as to control the width of the first circuit layer 23 and the width of the second circuit layer 35 in the etching process easily to achieve finer line pitch.

Therefore, the present disclosure utilizes the first organic conductive layer 21 and the second organic conductive layer 33 to replace the copper layer of the conventional modified semi-additive process (MSAP) so as to reduce the side etching amount of circuit in the prior art, thus the required first circuit layer 23 and the required second circuit layer 35 with fine line width/fine line pitch can be fabricated by using the improved MSAP fabricating process. Besides, the fabricating method of the present disclosure has low cost, high productivity and great yield, and is conducive to fabricate the first circuit layer 23 and the second circuit layer 35 with fine line width/fine line pitch (e.g., less than 10/13 micrometers).

The present disclosure provides a package substrate 3, which comprises: a core layer 200, a first metal layer 201, a first organic conductive layer 21 and a patterned second metal layer 22, such that the second metal layer 22, the first organic conductive layer 21 and the first metal layer 201 are served as a first circuit layer 23.

The package substrate 3 further comprises at least one second circuit layer 35 formed on the first circuit layer 23 and electrically connected to the first circuit layer 23.

The second circuit layer 35 comprises a third metal layer 32, a second organic conductive layer 33 and a fourth metal layer 34, such that the fourth metal layer 34, the second organic conductive layer 33 and the third metal layer 32 are served as the second circuit layer 35.

The first circuit layer 23 and the second circuit layer 35 are both formed with a plurality of patterned openings.

The first organic conductive layer 21 and the second organic conductive layer 33 are both made of graphite.

A thickness of the first organic conductive layer 21 and a thickness of the second organic conductive layer 33 are both at least 0.3 μm.

A thickness of the first metal layer 201 and a thickness of the third metal layer 32 are both in a range of 1.5 μm to 2.5 μm.

A line pitch of the first circuit layer 23 and a line pitch of the second circuit layer 35 are both in a range of 10 μm to 13 μm.

The package substrate 3 further comprises an insulating layer 36 with at least one opening 360 formed on the second circuit layer 35, and an electrode pad 361 formed in the opening 360 and electrically connected to the second circuit layer 35.

To sum up, in the package substrate and the fabricating method thereof of the present disclosure, the designs of the organic conductive layers are utilized to facilitate the control of the side etching amount of the metal circuit during etching, thereby facilitating the fabrication of the circuit layers with fine line width/fine line pitch.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a core board body having a core layer and a first metal layer formed on two opposite surfaces of the core layer;
a first organic conductive layer formed on the first metal layer; and
a patterned second metal layer formed on the first organic conductive layer, wherein the first organic conductive layer and the first metal layer are formed with patterns corresponding to the second metal layer, and the second metal layer, the first organic conductive layer and the first metal layer are served as a first circuit layer.

2. The package substrate of claim 1, further comprising a second circuit layer formed on and electrically connected to the first circuit layer, wherein the second circuit layer and the first circuit layer have a dielectric layer formed therebetween.

3. The package substrate of claim 2, wherein the second circuit layer comprises:
a third metal layer formed on the dielectric layer;
a second organic conductive layer formed on the third metal layer; and
a fourth metal layer formed on the second organic conductive layer, wherein the second organic conductive layer and the third metal layer are formed with patterns corresponding to a pattern of the fourth metal layer, and the fourth metal layer, the second organic conductive layer and the third metal layer are served as the second circuit layer.

4. The package substrate of claim 3, wherein the first organic conductive layer and the second organic conductive layer are made of graphite.

5. The package substrate of claim 3, wherein a thickness of the first organic conductive layer and a thickness of the second organic conductive layer are at least 0.3 μm.

6. The package substrate of claim 3, wherein a thickness of the first metal layer and a thickness of the third metal layer are 1.5 μm to 2.5 μm.

7. The package substrate of claim 3, wherein a line pitch of the first circuit layer and a line pitch of the second circuit layer are 10 μm to 13 μm.

8. The package substrate of claim 2, further comprising:
an insulating layer formed on the second circuit layer and having an opening; and
an electrode pad formed in the opening and electrically connected to the second circuit layer.

9. The package substrate of claim 2, wherein the first circuit layer and the second circuit layer are formed with a plurality of patterned openings.

10. A method of fabricating a package substrate, comprising:
providing a core board body, wherein the core board body has a core layer and a first metal layer formed on two opposite surfaces of the core layer;
forming a first organic conductive layer on the first metal layer;
forming a patterned second metal layer on the first organic conductive layer; and
removing portions of the first organic conductive layer and the first metal layer respectively according to a pattern of the second metal layer, wherein the second metal layer, the first organic conductive layer and the first metal layer are served as a first circuit layer.

11. The method of claim 10, further comprising forming a second circuit layer on the first circuit layer, wherein the second circuit layer is electrically connected to the first circuit layer, and the second circuit layer and the first circuit layer have a dielectric layer formed therebetween.

12. The method of claim 11, wherein a method of forming the second circuit layer comprises:
forming a third metal layer on the dielectric layer;
forming a second organic conductive layer on the third metal layer;
forming a fourth metal layer on the second organic conductive layer; and
removing portions of the second organic conductive layer and the third metal layer respectively according to a pattern of the fourth metal layer, wherein the fourth metal layer, the second organic conductive layer and the third metal layer are served as the second circuit layer.

13. The method of claim 12, wherein the first organic conductive layer and the second organic conductive layer are made of graphite.

14. The method of claim 12, wherein a thickness of the first organic conductive layer and a thickness of the second organic conductive layer are at least 0.3 μm.

15. The method of claim 12, wherein a thickness of the first metal layer and a thickness of the third metal layer are 1.5 μm to 2.5 μm.

16. The method of claim 12, wherein a line pitch of the first circuit layer and a line pitch of the second circuit layer are 10 μm to 13 μm.

17. The method of claim 11, further comprising:
forming an insulating layer with an opening on the second circuit layer; and
forming an electrode pad in the opening to electrically connect the second circuit layer.

18. The method of claim 11, wherein the first circuit layer and the second circuit layer are formed with a plurality of patterned openings.
